(19) United States
(12) Patent Application Publication
(10) Pub. No.: US 2026/0123204 A1
(43) Pub. Date: Apr. 30, 2026

(54) DISPLAY PANEL AND DISPLAY DEVICE

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/358,791

(22) Filed: Oct. 15, 2025

(30) Foreign Application Priority Data
Oct. 31, 2024 (CN) 202411550663.0

(51) Int. Cl. H10K 59/127; H10K 59/122; H10K 59/38; H10K 59/80; H10K 102/00

(52) U.S. Cl. CPC H10K 59/1275; H10K 59/122; H10K 59/38; H10K 59/80518; H10K 59/878; H10K 59/8792; H10K 2102/351

(57) ABSTRACT

A display panel, and a display device. The display panel includes a silicon-based drive substrate, a glass substrate, a pixel definition layer, multiple light-emitting units, and a light conversion layer. The glass substrate defines a conductive through hole; the conductive through hole is filled with a conductive portion; the pixel definition layer protrudes forms an open region, and the conductive portion is exposed through the open region; each light-emitting unit includes a first electrode, a light-emitting layer, and a second electrode; the first electrode is electrically connected to the conductive portion; the light conversion layer is configured to receive at least a portion of an incident light beam, where the incident light beam includes an invisible light, and the light conversion layer is configured to convert at least a portion of the invisible light into a visible light for emission.

### CROSS-REFERENCE TO RELATED APPLICATIONS

The present application claims priority of Chinese Patent Application No. 202411550663.0, filed on Oct. 31, 2024, the entire contents of which are hereby incorporated by reference in their entirety.

### TECHNICAL FIELD

The present disclosure relates to the field of display technologies, and in particular to a display panel and a display device.

### BACKGROUND

Organic Light Emitting Diode (OLED), also referred to as Organic Electroluminesence Display (OELD), represents a cutting-edge advancement in display technology. Its advantages, such as superior contrast ratios, wide viewing angles, flexibility, lightweight design, and energy efficiency, surpass those of traditional liquid crystal displays (LCDs), making OLED a widely adopted and promising direction in modern display innovation.

However, existing OLED display panels are significantly affected by external incident light, particularly invisible wavelengths such as ultraviolet (UV) radiation. Prolonged exposure to such light induces structural degradation in internal components and thin-film layers, which substantially accelerates the operational lifespan reduction of the panels.

### SUMMARY OF THE DISCLOSURE

The present disclosure provides a display panel, including:
a silicon-based drive substrate;
a glass substrate, connected to the silicon-based drive substrate; wherein the glass substrate defines a conductive through hole running through surfaces on opposite sides of the glass substrate;
the conductive through hole is filled with a conductive portion;
a pixel definition layer, disposed on the glass substrate; wherein the pixel definition layer protrudes from the glass substrate and forms an open region, and the conductive portion is exposed through the open region on a side of the glass substrate away from the silicon-based drive substrate;
a plurality of light-emitting units; wherein each of the plurality of light-emitting units is at least partially disposed in the open region and includes a first electrode, a light-emitting layer, and a second electrode that are cascaded; the first electrode is electrically connected to the conductive portion; and
a light conversion layer, disposed on a side of the glass substrate away from the silicon-based drive substrate; wherein the pixel definition layer covers the light conversion layer; the light conversion layer is configured to receive at least a portion of an incident light beam;
wherein the incident light beam includes an invisible light, and the light conversion layer is further configured to convert at least a portion of the invisible light into a visible light for emission.

The present disclosure further provides a display device, including the display panel as above.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a structural schematic view of a display device according to some embodiments of the present disclosure.

FIG. 2 is a first structural schematic view of a display panel according to some embodiments of the present disclosure.

FIG. 3 is a second structural schematic view of a display panel according to some embodiments of the present disclosure.

FIG. 4 is a third structural schematic view of a display panel according to some embodiments of the present disclosure.

### DETAILED DESCRIPTION

The technical solutions in the embodiments of the present disclosure will be described in detail with reference to the accompanying drawings. The following embodiments are provided solely to illustrate the technical solutions of the present disclosure and are therefore only examples and should not be intended to limit the scope of the present disclosure.

Unless otherwise defined, all technical and scientific terms used herein have the same meanings as generally understood by those skilled in the art to which the present disclosure relates. The terms used herein are intended to describe specific embodiments and are not intended to limit the present disclosure. The terms “include” and “have” and any variations thereof used in the description, claims, and accompanying drawings of the present disclosure are intended to cover non-exclusive inclusion.

In the description of the embodiments of the present disclosure, the technical terms “first”, “second”, etc. are only intended to distinguish different objects, and are not to be construed as indicating or implying relative importance, or implicitly specifying the number, specific order, or primary and secondary relationship of the technical features indicated. In the description of the embodiments of the present disclosure, “more than one” means more than two, unless otherwise expressly and specifically limited.

Reference to “embodiments” herein implies that a particular feature, structure, or characteristic described in conjunction with an embodiment may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

In the description of embodiments of the present disclosure, the term “and/or” is merely an associative relationship describing an associated object, indicating that three types of relationships may exist, such as A and/or B, which may indicate: the existence of A alone, the existence of both A and B, and the existence of B alone. In addition, the character “/” herein generally indicates that the associated objects are in an “or” relationship.

In the description of the embodiments of the present disclosure, the term “plurality” refers to more than two (including two), and similarly, “multiple groups” refers to more than two (including two), and “multiple tablets” refers to more than two (including two).

In the description of embodiments of the present disclosure, the technical terms “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “radial”, “peripheral”, etc. indicate orientations or positional relationships based on those shown in the accompanying drawings, and are intended only to facilitate the description of the embodiments of the present disclosure and to simplify the description, and are not intended to indicate or imply that the device or element referred to must have a particular orientation, be constructed and operated with a particular orientation, and therefore are not to be construed as a limitation of the embodiments of the present disclosure.

In the description of the embodiments of the present disclosure, unless otherwise expressly provided and limited, the technical terms “mounted”, “connected”, “coupled”, “fixed”, and the like shall be understood in a broad sense, for example, it may be a fixed connection, a detachable connection, or a one-piece connection; it may be a mechanical connection, or an electrical connection; it may be a direct connection, or an indirect connection through an intermediate medium, and it may be a connectivity within the two elements or an interactive relationship between the two elements. For those skilled in the art, the specific meanings of the above terms in the embodiments of the present disclosure may be understood on a case-by-case basis.

Organic Light Emitting Diode (OLED), also referred to as Organic Electroluminesence Display (OELD), represents a cutting-edge advancement in display technology. Its advantages, such as superior contrast ratios, wide viewing angles, flexibility, lightweight design, and energy efficiency, surpass those of traditional liquid crystal displays (LCDs), making OLED a widely adopted and promising direction in modern display innovation.

However, existing OLED display panels are significantly affected by external incident light, particularly invisible wavelengths such as ultraviolet (UV) radiation. Prolonged exposure to such light induces structural degradation in internal components and thin-film layers, which substantially accelerates the operational lifespan reduction of the panels.

The present disclosure provides a display device, and the display device may include, but is not limited to, a mobile phone, a tablet, a laptop, a desktop, a terminal, an interactive display, a digital audio/video device, an Internet of Things (IoT) device, and the like. The interactive display may include an interactive whiteboard, a digital advertising interactive screen, and a gaming interactive display, etc. The IoT device may include a smart home device and a smart wearable device, etc. The display device may include a display panel, and the display device may provide a display interface and a touch input through the display panel to realize a corresponding function.

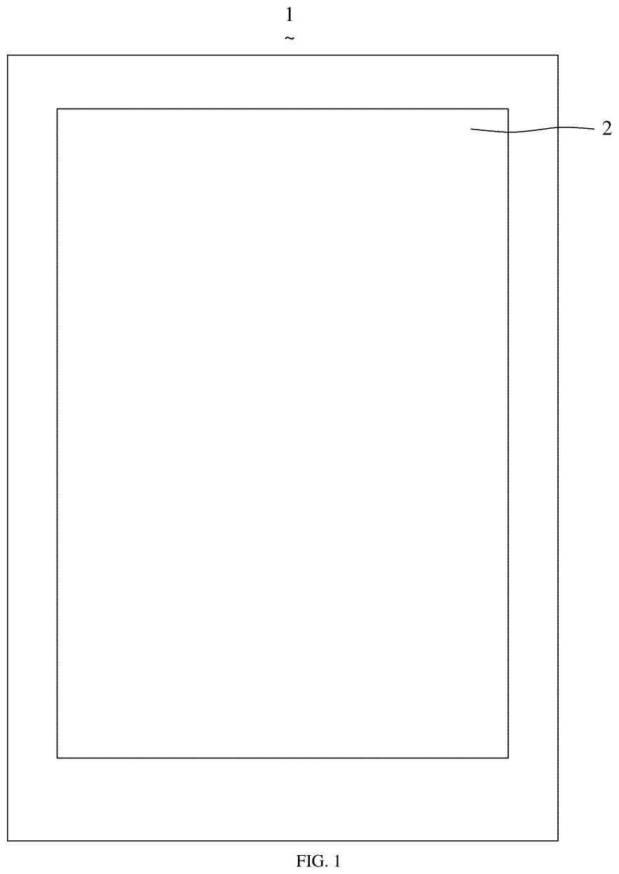

Referring to FIG. 1, FIG. 1 is a structural schematic view of a display device according to some embodiments of the present disclosure.

The display device 1 may be an ordinary mobile phone, a feature phone, or a smartphone, and the smartphone may be a flat-screen phone, a curved-screen phone, or a foldable phone, etc. The display device 1 is arranged with a display panel 2, and the display panel 2 may be disposed on a head portion or a middle portion or a tail portion of the display device 1. The display panel 2 may be configured to display information of the display device 1, for example, the display panel 2 may serve as a visual information display portion of the display device 1. The display panel 2 may further serve as a touch information input portion, for facilitating a user's operation of the display device 1 by means of touching the display panel 2, e.g., for realizing the displaying and inputting requirements for interface navigation and function switching of the display device 1.

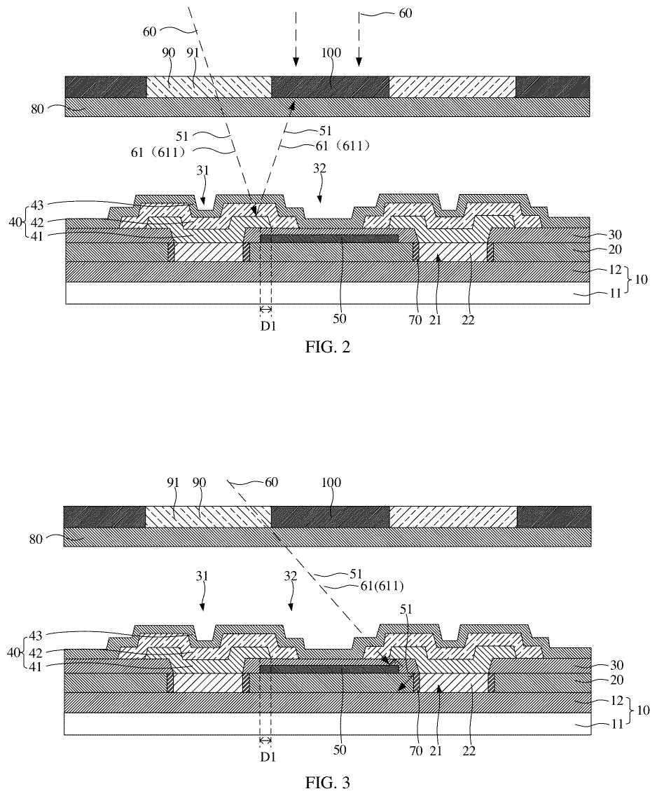

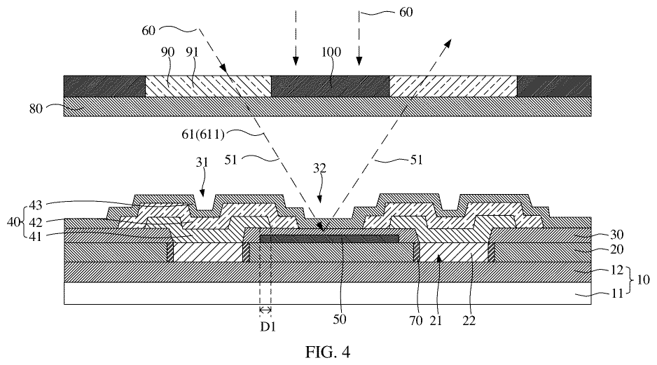

Referring to FIGS. 2-4, FIG. 2 is a first structural schematic view of a display panel according to some embodiments of the present disclosure, FIG. 3 is a second structural schematic view of a display panel according to some embodiments of the present disclosure, and FIG. 4 is a third structural schematic view of a display panel according to some embodiments of the present disclosure.

To solve the above problems, the present disclosure provides a display panel 2, the display panel 2 including a silicon-based drive substrate 10, a glass substrate 20, a pixel definition layer 30, multiple light-emitting units 40, and a light conversion layer 50. The glass substrate 20 is connected to the silicon-based drive substrate 10; the glass substrate 20 defines a conductive through hole 21 running through surfaces on opposite sides of the glass substrate 20; the conductive through hole 21 is filled with a conductive portion 22; the pixel definition layer 30 is disposed on the glass substrate 20; the pixel definition layer 30 protrudes from the glass substrate 20 and forms an open region 31, and the conductive portion 22 is exposed through the open region 31 on a side of the glass substrate 20 away from the silicon-based drive substrate 10; the multiple light-emitting units 40 are at least partially disposed in the open region 31, and each of the multiple light-emitting units 40 includes a first electrode 41, a light-emitting layer 42, and a second electrode 43 that are cascaded; the first electrode 41 is electrically connected to the conductive portion 22; the light conversion layer 50 is disposed on a side of the glass substrate 20 away from the silicon-based drive substrate 10, and the pixel definition layer 30 covers the light conversion layer 50; the light conversion layer 50 is configured to receive at least a portion of an incident light beam 60, where the incident light beam 60 includes an invisible light 61, and the light conversion layer 50 is configured to convert at least a portion of the invisible light 61 into a visible light 51 for emission.

The glass substrate 20 is connected to the silicon-based drive substrate 10. The glass substrate 20 may be connected to the silicon-based drive substrate 10 through the conductive through holes 21 running through the surfaces on the opposite sides of the glass substrate 20, and the conductive through holes 21 may be filled with the conductive portions 22 to be electrically connected to the silicon-based drive substrate 10. The material of the conductive portion 22 may include, but is not limited to, metal and electrically conductive flexible organic composites, etc. The silicon-based drive substrate 10 may include a silicon-based substrate 11 and a drive circuit layer 12, the drive circuit layer 12 being disposed on a side of the silicon-based substrate 11 near the glass substrate 20.

The silicon-based substrate 11 refers to a substrate plate based on a monocrystalline silicon material.

The drive circuit layer 12 includes an active drive circuit (not shown) integrated on the silicon-based substrate 11 using a Complementary Metal-Oxide-Semiconductor (CMOS) process.

In the fabrication process, the silicon-based drive substrate 10 is prepared separately from the glass substrate 20, which may improve the production efficiency and further avoid the effect of the vapor deposition process on the silicon-based drive substrate 10, reducing the loss of the silicon-based drive substrate 10. In other words, from a process perspective, the separate preparation of the silicon-based drive substrate 10 and the glass substrate 20 may not only improve the yield, but also reduce the cost.

It should be understood that the glass through-hole technology has the advantages of excellent high-frequency electrical characteristics, low cost, simple process flow, and high mechanical stability compared to the silicon through-hole technology.

The pixel definition layer 30 protrudes from the drive substrate and forms an open region 31, and the multiple light-emitting units 40 are disposed in the open region 31. The pixel definition layer 30 may define the positions of the light-emitting units 40 through the open region 31, such that the light-emitting units 40 are provided in suitable positions. The material of the pixel definition layer 30 may be one of an organic material, an organic material with an inorganic coating provided thereon, or an inorganic material. The organic material of the pixel definition layer 30 includes, but is not limited to, polyimide. The inorganic material of the pixel definition layer 30 includes, but is not limited to, silicon oxide (SiO₂), silicon nitride (Si₃N₄), silicon nitride oxide (Si₂N₂O), magnesium fluoride (MgF₂), or a combination thereof. The specific material of the pixel-definition layer 30 is not limited and is selected according to actual needs. As a result, adjacent light-emitting units 40 may be isolated by the pixel-definition layer 30, thereby reducing the risk of crosstalk between the multiple light-emitting units 40.

The light-emitting layer 42 of the light-emitting unit 40 may emit light beams in an energized state, and the light-emitting layers 42 of the multiple light-emitting units 40 have different light-emitting colors. For example, each of the light-emitting layers 42 emits one of red light, blue light, and green light when energized. The first electrode 41 and the second electrode 43 are configured to energize the light-emitting layer 42, and exemplarily, the first electrode 41 may be an anode electrode and the second electrode 43 may be a cathode electrode.

The light conversion layer 50 is disposed on a side of the glass substrate 20 away from the silicon-based drive substrate 10, the pixel definition layer 30 covers the light conversion layer 50, and the light conversion layer 50 is configured to receive at least a portion of the incident light beam 60. The incident light beam 60 includes the invisible light 61, and the light conversion layer 50 is configured to convert at least a portion of the invisible light 61 into the visible light 51 for emission. The incident light beam 60 is ambient light that is emitted into the interior of the display panel 2 from the exterior of the display panel 2, where the incident light beam 60 may be natural light, such as sunlight, etc., or artificial light, such as light beams emitted from external light emitting devices. It is to be understood that the incident light beam 60 may include a variety of wavelengths. The incident light beam 60 includes the invisible light 61, such as infrared light, ultraviolet (UV) light, high-energy rays, and the like, and it is to be noted that the invisible light 61 that is invisible for the human eye, such as ultraviolet light 611, cannot be directly used to compensate for the luminance of the display panel 2, whereas the light conversion layer 50 may convert at least some of the invisible light 61 into the visible light 51 visible to the human eye. Exemplarily, the light conversion layer 50 may be an aerogel.

For example, Prof. Haibo ZHAO, from the team of academician Yuzhong WANG in the State Local Joint Engineering Laboratory of Environmentally Friendly Polymer Materials of Sichuan University, proposed a new strategy for radiation cooling based on biomass intrinsic photoluminescence, and developed an all-biomass radiation-cooling aerogel that has a high solar reflectivity and can be recycled. The biomass aerogel (GE/DNA) prepared from gelatin (GE) and DNA has unique fluorescent/phosphorescent properties as well as a highly ordered layered structure. This intrinsic photoluminescence effect allows the aerogel to convert absorbed UV light into visible light, effectively increasing the solar-weighted reflectance of the aerogel material in the visible region (up to 104.0% under sunlight simulation), thereby dramatically gaining the daytime radiative cooling efficiency of the aerogel material, and lowering the ambient temperature by up to 16.0° C. under the outdoor conditions of high solar irradiance. On the other hand, by utilizing the reversible dissociation-reconstruction of strong ionic hydrogen bonds at the water-mediated aerogel interface, the large-scale preparation of aerogel panels with anisotropic pore structure was achieved by a scalable and universal water welding strategy, and the long-range ordered pore structure ensures the reliability of the optical properties and comprehensive performance of the aerogel material. In addition, the all-biomass aerogel material is flame retardant, rapidly self-repairable, recyclable and biodegradable, and is highly environmentally friendly throughout the life cycle of material source, preparation, use and disposal.

In addition, it should be noted that the ultraviolet light 611 in the invisible light 61 has a greater impact on the internal structure of the display panel 2. For example, the conductive portion 22 absorbs the ultraviolet light 611 resulting in heat generation, and the heat generation phenomenon is particularly serious when the material of the conductive portion 22 is a conductive flexible organic compound. Further, when the pixel definition layer 30 is subjected to the UV light 611 for a long time, there is also a risk of accelerated aging, etc., and the internal base structure of the display panel 2 is prone to heat generation after absorbing the UV light 611. The silicon-based driver member is more sensitive to the temperature, and high temperature will seriously affect the device characteristics of the silicon-based driver member, resulting in the risk of the silicon-based drive substrate 10 aging or the output abnormality.

It should be understood that in the proposed technical scheme, the light conversion layer 50 is disposed on the side of the glass substrate 20 away from the silicon-based drive substrate 10, the pixel definition layer 30 covers the light conversion layer 50, and the light conversion layer 50 can convert at least some of the invisible light 61, such as UV light 611, etc., that is injected into the pixel definition layer 30 into the visible light 51 of a much lower energy for emission, which may reduce the damage that the invisible light 61, such as UV light 611, can cause to the internal devices of the display panel 2. In addition, the converted visible light 51 can be co-emitted with the light beam emitted by the light-emitting unit 40, thereby utilizing the converted visible light 51 to compensate for the brightness of the light-emitting unit 40, and thus improving the brightness of the display panel 2.

Through the above implementations, the light conversion layer 50 can convert the invisible light 61 in the incident light beam 60 into the visible light 51 for emission, thereby mitigating the risk of damage to the internal film layers of the display panel 2 and accelerated aging under the irradiation of external incident light, and thus prolonging the service life of the display panel 2. In addition, the incident light beam 60 can be fully utilized by converting the invisible light 61 in the incident light beam 60 into the visible light 51 for emission, thereby compensating for the brightness of the light-emitting unit 40 and improving the brightness of the display panel 2.

In some embodiments, the first electrode 41 is a reflective electrode for blocking and reflecting the light beam, and a positive projection of the light conversion layer 50 on the glass substrate 20 at least partially coincides with a positive projection of the first electrode 41 of an adjacent light-emitting unit 40 on the glass substrate 20. The material of the first electrode 41 may include, but is not limited to, chromium, titanium, gold, silver, copper, aluminum, ITO, combinations thereof, or other suitable conductive materials. The first electrode 41 can block the received light beam and reflect it. Exemplarily, the first electrode 41 may be an anode electrode, and it is noted that the light emitting layer 42 and the second electrode 43 are transparent, and the incident light beam 60 may be transmissible through the light emitting layer 42 and the second electrode 43, whereby the positive projection of the light conversion layer 50 on the glass substrate 20 at least partially overlaps with the positive projection of the first electrode 41 of the adjacent light-emitting unit 40 on the glass substrate 20, thereby facilitating the light conversion layer 50 to cooperate with the first electrode 41 to completely cover the silicon-based drive substrate 10 in a direction perpendicular to the glass substrate 20, reducing the risk of the incident beam 60 being directly incident on the glass substrate 20 and the silicon-based drive substrate 10 through a gap between the light conversion layer 50 and the first electrode 41, as compared to the manner in which the positive projection of the light conversion layer 50 does not coincide with the positive projection of the first electrode 41. In some embodiments, the light conversion layer 50 should be at least of a certain length, and exemplarily, the length should be such that there is no angle between the light conversion layer 50 and the adjacent first electrode 41 that can allow the incident light beam 60 to be directly irradiated to the conductive portion 22 along a straight line light path. As shown in FIG. 2, when the incident light beam 60 is directly irradiated to the surface of the first electrode 41, both the invisible light 61 and the visible light 51 in the incident light beam 60 are directly reflected by the first electrode 41.

In some embodiments, a length D1 of a portion of the light conversion layer 50 whose positive projection on the glass substrate 20 coincides with the positive projection of the first electrode 41 of the adjacent light-emitting unit 40 on the glass substrate 20 is greater than or equal to 0.5 μm and is less than or equal to 1 μm. For example, the length D1 may be in a range from 0.5 μm to 0.7 μm; or from 0.6 μm to 1 μm; or from 0.6 μm to 0.7 μm, etc. Specifically, the length D1 of the overlapping portion may be 0.5 μm, 0.6 μm, 0.7 μm, 0.8 μm, 0.85 μm, 1 μm, etc., including but not limited to these values. As a result, the light conversion layer 50 can receive more invisible light 61, thereby reducing the risk of damage to internal structures such as the conductive portion 22 and the pixel definition layer 30 caused by the invisible light 61, e.g., the ultraviolet light 611.

In some embodiments, a thickness of the light conversion layer 50 in the direction perpendicular to the glass substrate 20 is greater than or equal to 1000 Å and less than or equal to 3000 Å. Exemplarily, the thickness may be in a range from 1000 Å to 2000 Å; or from 1500 Å to 2500 Å; or from 2000 Å to 3000 Å; and so forth. Specifically, the thickness may include, but not limited to, 1000 Å, 1200 Å, 1500 Å, 1800 Å, 2000 Å, 2800 Å, 3000 Å, and the like. As a result, it may be convenient for the light conversion layer 50 to be set to a suitable thickness, reduce the difficulty of flattening the pixel definition layer 30, and reduce the risk of the first electrode 41 having a large climb or multiple climbs at the cascade with the light conversion layer 50 due to the thickness of the light conversion layer 50 being too large.

In some embodiments, the display panel 2 further includes a light reflection layer 70, the light reflection layer 70 being disposed between the conductive portion 22 and an inner side wall of the conductive through hole 21 for blocking and reflecting at least a portion of the visible light 51. The light reflection layer 70 may reflect the visible light 51 arriving at the conductive through hole 21. It is to be noted that, as shown in FIG. 3, at least a portion of the invisible light 61 will be converted into the visible light 51 by the light conversion layer 50 and reflected to a side of the first electrode 41 close to the glass substrate 20, and this portion of the visible light 51 will be reflected several times between the light conversion layer 50 and the first electrode 41 and finally arrive at the conductive through hole 21. The light reflective layer 70 may reflect this portion of the visible light 51 in a direction toward the silicon-based drive substrate 10. It can be understood that this portion of the visible light 51 is converted from the invisible light 61 by the light conversion layer 50, and compared to the non-converted invisible light 61 directly irradiated to the silicon-based drive substrate 10, this portion of the visible light 51 has lower energy, lower light intensity, and a smaller impact on the silicon-based drive substrate 10. In some application scenarios, the light reflective layer 70 may be made of the same material as the light conversion layer 50. As a result, a small portion of the visible light 51 that can reach the conductive through hole 21 can be reflected by the light reflection layer 70, thereby further reducing the risk of the conductive portion 22 being heated and damaged by the incident light beam 60, and thus extending the service life of the display panel 2.

In some embodiments, a thickness of the light reflective layer 70 in a radial direction of the conductive through hole 21 is less than or equal to 1000 Å. Exemplarily, the thickness of the light reflective layer 70 may be in a range from 500 Å to 700 Å; or from 700 Å to 900 Å; or from 900 to 1000 Å. Specifically, the thickness of the light reflective layer 70 may be 600 Å, 700 Å, 750 Å, 800 Å, 900 Å, 1000 Å, and the like. As a result, the influence of the light reflective layer 70 on the connecting effect between the glass substrate 20 and the silicon-based drive substrate 10 may be reduced, thereby mitigating the risk of connecting failure due to excessive thickness of the light reflective layer 70.

In some embodiments, the display panel 2 further includes a color film substrate 80 and a color filter layer 90, the color film substrate 80 is disposed on a side of the light-emitting unit 40 away from the glass substrate 20, the color filter layer 90 is disposed on a side of the color film substrate 80 away from the light-emitting unit 40, and the color filter layer 90 is configured to filter the received light beam for emission. The color film substrate 80 may provide support and protection for the color filter layer 90, and the color filter portion 91 may include a red filter portion, a green filter portion, and a blue filter portion for selecting the color of light transmitted through the color filter layer 90 to form a pixel unit. According to the combination of the red filter portion, the green filter portion, and the blue filter portion of the individual pixels, it may be easy to adjust the color of the light, so as to make the display panel 2 present a colorful image. The color filter portion 91 is disposed in correspondence with and facing the light-emitting unit 40 of the same color. Exemplarily, the red filter portion is disposed facing the red light-emitting unit 40, the green filter portion is disposed facing the green light-emitting unit 40, and the blue filter portion is disposed facing the blue light-emitting unit 40. It is noted that at least a portion of the invisible light 61 in the incident light beam 60 may be transmitted into the display panel 2 through the color filter portion 91, for example, the ultraviolet light 611. In some application scenarios, as shown in FIG. 4, the incident light beam 60 is transmitted through the color filter portion 91 to the light conversion layer 50 and exits through another color filter portion 91. Ideally, taking the incident light beam 60 as sunlight and being incident through the red filter portion and emitted from the green filter portion as an example, before the incident light beam 60 passes through the red filter portion, the incident light beam 60 includes visible light 51 of a variety of colors and invisible light 61, and the invisible light 61 includes ultraviolet light 611; after the incident light beam 60 passes through the red filter portion, the visible light 51 other than red light in the incident light beam 60 is blocked by the red filter portion, and the incident light beam 60 includes only the red light and the invisible light 61, where the invisible light 61 includes the ultraviolet light 611; when the incident light beam 60 arrives at the light conversion layer 50, the invisible light 61 is converted into a variety of colors of the visible light 51, and the visible light 51 of a variety of colors converted from the invisible light 61 and the original red light in the incident light beam 60 are reflected together into the green filter portion, and the visible light 51 other than green light is blocked by the green filter portion, i.e., only the green light in the visible light 51 of the multiple colors formed by the conversion of the invisible light 61 is emitted through the green filter portion, thereby compensating the brightness of the green light-emitting unit 40 corresponding to the green filter portion.

In some embodiments, the display panel 2 further includes a black matrix 100, the black matrix 100 and the color filter layer 90 are disposed in the same layer and embedded in the color filter layer 90, and the black matrix 100 is configured to block and reflect at least a portion of the incident light beams 60. The material of the black matrix 100 may be a black organic dye or a black organic resin. The black matrix 100 may be disposed facing a position between the light-emitting units 40, and the black matrix 100 may reduce the leakage of light from the red filter portion, the green filter portion, and the blue filter portion and the mutual interference of light from the individual pixel units, thereby enhancing the contrast and clarity of the image. In addition, the black matrix 100 may block external light beams from entering the interior of the display panel 2, thereby reducing the risk of invisible light 61, such as ultraviolet light 611, entering the display panel 2.

In some embodiments, the black matrix 100 is disposed in correspondence with and facing the light conversion layer 50 in a direction perpendicular to the glass substrate 20. It should be noted that the invisible light 61 incident to the light conversion layer 50 along the direction perpendicular to the glass substrate 20 will return along the original light path after being converted into the visible light 51, making it difficult to compensate the brightness of the light-emitting unit 40. As a result, the arrangement of the black matrix 100 in correspondence with the light conversion layer 50 in the direction perpendicular to the glass substrate 20 may reduce the risk of the invisible light 61, which is difficult to utilize, entering the display panel 2.

In summary, the present disclosure provides a display panel 2, including a silicon-based drive substrate 10, a glass substrate 20, a pixel definition layer 30, multiple light-emitting units 40, and a light conversion layer 50; the glass substrate 20 is connected to the silicon-based drive substrate 10; the glass substrate 20 defines a conductive through hole 21 running through surfaces on opposite sides of the glass substrate 20; the conductive through hole 21 is filled with a conductive portion 22; the pixel definition layer 30 is disposed on the glass substrate 20; the pixel definition layer 30 protrudes from the glass substrate 20 and forms an open region 31, and the conductive portion 22 is exposed through the open region 31 on a side of the glass substrate 20 away from the silicon-based drive substrate 10; the multiple light-emitting units 40 are at least partially disposed in the open region 31, and each of the multiple light-emitting units 40 includes a first electrode 41, a light-emitting layer 42, and a second electrode 43 that are cascaded; the first electrode 41 is electrically connected to the conductive portion 22; the light conversion layer 50 is disposed on a side of the glass substrate 20 away from the silicon-based drive substrate 10, and the pixel definition layer 30 covers the light conversion layer 50; the light conversion layer 50 is configured to receive at least a portion of an incident light beam 60, where the incident light beam 60 includes an invisible light 61, and the light conversion layer 50 is configured to convert at least a portion of the invisible light 61 into a visible light 51 for emission. By the above embodiment, the light conversion layer 50 can convert the invisible light 61 in the incident light beam 60 into a visible light 51 for emission, thereby mitigating the risk of damage to the internal film layers of the display panel 2 and accelerated aging under the irradiation of external incident light, and thus prolonging the lifespan of the display panel 2. In addition, the incident light beam 60 can be fully utilized by converting the invisible light 61 in the incident light beam 60 into the visible light 51 for emission, thereby compensating for the brightness of the light-emitting unit 40 and improving the brightness of the display panel 2.

Finally, it should be noted that the above embodiments are only intended to illustrate the technical solutions of the present disclosure, not to limit them. Although the present disclosure has been described in detail with reference to the foregoing embodiments, those skilled in the art should understand that he or she can still make modifications to the technical solutions documented in the foregoing embodiments, or make equivalent substitutions for some or all of the technical features therein. These modifications or substitutions do not detach the essence of the corresponding technical solutions from the scope of the technical solutions of the embodiments of the present disclosure, which shall be covered by the scope of the claims and the specification of the present disclosure. In particular, as long as there is no structural conflict, the technical features mentioned in the various embodiments can be combined in any way. The present disclosure is not limited to the particular embodiments disclosed herein, but includes all technical solutions falling within the scope of the claims.

1. A display panel, comprising:
a silicon-based drive substrate;
a glass substrate, connected to the silicon-based drive substrate; wherein the glass substrate defines a conductive through hole running through surfaces on opposite sides of the glass substrate;
the conductive through hole is filled with a conductive portion;
a pixel definition layer, disposed on the glass substrate; wherein the pixel definition layer protrudes from the glass substrate and forms an open region, and the conductive portion is exposed through the open region on a side of the glass substrate away from the silicon-based drive substrate;
a plurality of light-emitting units; wherein each of the plurality of light-emitting units is at least partially disposed in the open region and comprises a first electrode, a light-emitting layer, and a second electrode that are cascaded; the first electrode is electrically connected to the conductive portion; and
a light conversion layer, disposed on a side of the glass substrate away from the silicon-based drive substrate; wherein the pixel definition layer covers the light conversion layer; the light conversion layer is configured to receive at least a portion of an incident light beam;
wherein the incident light beam comprises an invisible light, and the light conversion layer is further configured to convert at least a portion of the invisible light into a visible light for emission.

2. The display panel according to claim 1, wherein the first electrode is a reflective electrode for blocking and reflecting light beams, and a positive projection of the light conversion layer on the glass substrate at least partially coincides with a positive projection of the first electrode of one of the plurality of light-emitting units on the glass substrate; the one of the plurality of light-emitting units is adjacent to the light conversion layer.

3. The display panel according to claim 2, wherein the positive projection of a portion of the light conversion layer on the glass substrate coincides with the positive projection of the first electrode of the one of the plurality of light-emitting units on the glass substrate; a length of the portion of the light conversion layer is greater than or equal to 0.5 μm and less than or equal to 1 μm.

4. The display panel according to claim 2, wherein a thickness of the light conversion layer in a direction perpendicular to the glass substrate is greater than or equal to 1000 Å and less than or equal to 3000 Å.

5. The display panel according to claim 2, further comprising a light reflection layer; wherein the light reflection layer is disposed between the conductive portion and an inner side wall of the conductive through hole for blocking and reflecting at least a portion of the visible light.

6. The display panel according to claim 5, wherein a thickness of the light reflective layer in a radial direction of the conductive through hole is less than or equal to 1000 Å.

7. The display panel according to claim 1, further comprising a color film substrate and a color filter layer; wherein the color film substrate is disposed on a side of the plurality of light-emitting units away from the glass substrate, and the color filter layer is disposed on a side of the color film substrate away from the plurality of light-emitting units; the color filter layer is configured to filter a received light beam for emission.

8. The display panel according to claim 7, further comprising a black matrix; wherein the black matrix and the color filter layer are disposed in a same layer and embedded in the color filter layer, and the black matrix is configured to block and reflect at least a portion of the incident light beams.

9. The display panel according to claim 8, wherein the color filter layer comprises a plurality of color filter portions that are spaced apart, and the black matrix is disposed between each adjacent two of the plurality of color filter portions; each color filter portion is arranged facing a corresponding light-emitting unit, and a color of the color filter portion is the same as a light-emitting color of the corresponding light-emitting unit.

10. The display panel according to claim 8, wherein the black matrix is disposed in correspondence with and facing the light conversion layer in a direction perpendicular to the glass substrate.

11. A display device, comprising a display panel;
wherein the display panel comprises:
a silicon-based drive substrate;
a glass substrate, connected to the silicon-based drive substrate; wherein the glass substrate defines a conductive through hole running through surfaces on opposite sides of the glass substrate; the conductive through hole is filled with a conductive portion;
a pixel definition layer, disposed on the glass substrate; wherein the pixel definition layer protrudes from the glass substrate and forms an open region, and the conductive portion is exposed through the open region on a side of the glass substrate away from the silicon-based drive substrate;
a plurality of light-emitting units; wherein each of the plurality of light-emitting units is at least partially disposed in the open region and comprises a first electrode, a light-emitting layer, and a second electrode that are cascaded; the first electrode is electrically connected to the conductive portion; and
a light conversion layer, disposed on a side of the glass substrate away from the silicon-based drive substrate; wherein the pixel definition layer covers the light conversion layer; the light conversion layer is configured to receive at least a portion of an incident light beam;
wherein the incident light beam comprises an invisible light, and the light conversion layer is further configured to convert at least a portion of the invisible light into a visible light for emission.

12. The display device according to claim 11, wherein the first electrode is a reflective electrode for blocking and reflecting light beams, and a positive projection of the light conversion layer on the glass substrate at least partially coincides with a positive projection of the first electrode of one of the plurality of light-emitting units on the glass substrate; the one of the plurality of light-emitting units is adjacent to the light conversion layer.

13. The display device according to claim 12, wherein the positive projection of a portion of the light conversion layer on the glass substrate coincides with the positive projection of the first electrode of the one of the plurality of light-emitting units on the glass substrate; a length of the portion of the light conversion layer is greater than or equal to 0.5 μm and less than or equal to 1 μm.

14. The display device according to claim 12, wherein a thickness of the light conversion layer in a direction perpendicular to the glass substrate is greater than or equal to 1000 Å and less than or equal to 3000 Å.

15. The display device according to claim 12, wherein the display panel further comprises a light reflection layer; wherein the light reflection layer is disposed between the conductive portion and an inner side wall of the conductive through hole for blocking and reflecting at least a portion of the visible light.

16. The display device according to claim 15, wherein a thickness of the light reflective layer in a radial direction of the conductive through hole is less than or equal to 1000 Å.

17. The display device according to claim 11, wherein the display panel further comprises a color film substrate and a color filter layer; wherein the color film substrate is disposed on a side of the plurality of light-emitting units away from the glass substrate, and the color filter layer is disposed on a side of the color film substrate away from the plurality of light-emitting units; the color filter layer is configured to filter a received light beam for emission.

18. The display device according to claim 17, wherein the display panel further comprises a black matrix; wherein the black matrix and the color filter layer are disposed in a same layer and embedded in the color filter layer, and the black matrix is configured to block and reflect at least a portion of the incident light beams.

19. The display device according to claim 18, wherein the black matrix is disposed in correspondence with and facing the light conversion layer in a direction perpendicular to the glass substrate.

20. A display panel, comprising:
a silicon-based drive substrate;
a glass substrate, connected to the silicon-based drive substrate; wherein the glass substrate defines a conductive through hole running through surfaces on opposite sides of the glass substrate;
the conductive through hole is filled with a conductive portion;
a pixel definition layer, disposed on the glass substrate; wherein the pixel definition layer protrudes from the glass substrate and forms an open region, and the conductive portion is exposed through the open region on a side of the glass substrate away from the silicon-based drive substrate;
a plurality of light-emitting units; wherein each of the plurality of light-emitting units comprises a first electrode, a light-emitting layer, and a second electrode that are cascaded; the first electrode is electrically connected to the conductive portion; and
a light conversion layer, disposed on a side of the glass substrate away from the silicon-based drive substrate and between each adjacent two of the plurality of light-emitting units; wherein the pixel definition layer covers the light conversion layer; the light conversion layer is configured to receive at least a portion of an incident light beam; wherein the incident light beam comprises an invisible light, and the light conversion layer is further configured to convert at least a portion of the invisible light into a visible light for emission;
wherein the first electrode is a reflective electrode for blocking and reflecting light beams; the first electrode is filled in the open region and extends toward the light conversion layer adjacent to the first electrode; an extended portion of the first electrode is disposed on the pixel definition layer to cover a portion of the light conversion layer.
